(19) United States
(12) Patent Application Publication
(10) Pub. No.: US 2024/0284684 A1
(43) Pub. Date: Aug. 22, 2024

(54) SEMICONDUCTOR DEVICE AND MANUFACTURING METHOD THEREOF

(71) Applicant: Kioxia Corporation, Tokyo (JP)

(72) Inventors: Shinya WATANABE, Arakawa Tokyo (JP); Masahiro INOHARA, Fujisawa Kanagawa (JP); Tatsuo MIGITA, Nagoya Aichi (JP); Masayuki MIURA, Ota Tokyo (JP)

(73) Assignee: Kioxia Corporation, Tokyo (JP)

(21) Appl. No.: 18/426,703

(22) Filed: Jan. 30, 2024

(30) Foreign Application Priority Data
Feb. 21, 2023 (JP) 2023-025413

(51) Int. Cl. H10B 80/00; H01L 21/78; H01L 25/00; H01L 25/065; H01L 25/18

(52) U.S. Cl. CPC H10B 80/00; H01L 21/78; H01L 25/0657; H01L 25/18; H01L 25/50; H01L 2225/06506; H01L 2225/06562; H01L 2225/06586

(57) ABSTRACT

A semiconductor device according to the present embodiment includes a first semiconductor chip and a second semiconductor chip. The first semiconductor chip has a first upper surface on which a first electrode pad is formed. The second semiconductor chip has a first lower surface on which a second electrode pad directly joined to the first electrode pad is formed and a second upper surface that is opposite the first lower surface and on which a third electrode pad is formed. The area of the first lower surface is smaller than the area of the first upper surface. The barycenter of the first lower surface and the barycenter of the first upper surface are located at different positions in the in-plane direction of the first upper surface.

### CROSS REFERENCE TO RELATED APPLICATIONS

This application is based upon and claims the benefit of priority from the prior Japanese Patent Application No. 2023-025413, filed on Feb. 21, 2023, the entire contents of which are incorporated herein by reference.

### FIELD

The embodiments of the present invention relate to a semiconductor device and a manufacturing method thereof.

### BACKGROUND

In a semiconductor device in which two wafers are bonded, an unnecessary region increases when there is a mismatch between the sizes (areas) of semiconductor elements of the respective wafers.

### BRIEF DESCRIPTION OF THE DRAWINGS

FIG. 1 is a cross sectional view illustrating an example of the configuration of a semiconductor device according to a first embodiment;

FIG. 2 is a plan view illustrating the example of the configuration of the semiconductor device according to the first embodiment;

FIG. 3 is a cross sectional view illustrating the example of the configuration of the semiconductor device according to the first embodiment;

FIG. 4 is a cross sectional view illustrating the example of the configuration of the semiconductor device according to the first embodiment;

FIG. 5 is a cross sectional view illustrating an example of the configuration of a memory cell array and a transistor according to the first embodiment;

FIG. 6 is a cross sectional view illustrating an example of the configuration of a column-shaped part according to the first embodiment;

FIG. 7A is a cross sectional view illustrating an example of a method of manufacturing the semiconductor device according to the first embodiment;

FIG. 7B is a perspective view illustrating the example of the semiconductor device manufacturing method, following FIG. 7A;

FIG. 7C is a perspective view illustrating the example of the semiconductor device manufacturing method, following FIG. 7B;

FIG. 7D is a perspective view illustrating the example of the semiconductor device manufacturing method, following FIG. 7C;

FIG. 7E is a perspective view illustrating the example of the semiconductor device manufacturing method, following FIG. 7D;

FIG. 7F is a perspective view illustrating the example of the semiconductor device manufacturing method, following FIG. 7E;

FIG. 7G is a perspective view illustrating the example of the semiconductor device manufacturing method, following FIG. 7F;

FIG. 7H is a perspective view illustrating the example of the semiconductor device manufacturing method, following FIG. 7G;

FIG. 7I is a perspective view illustrating the example of the semiconductor device manufacturing method, following FIG. 7H;

FIG. 7J is a perspective view illustrating the example of the semiconductor device manufacturing method, following FIG. 7I;

FIG. 7K is a perspective view illustrating the example of the semiconductor device manufacturing method, following FIG. 7J;

FIG. 7L is a perspective view illustrating the example of the semiconductor device manufacturing method, following FIG. 7K;

FIG. 7M is a perspective view illustrating the example of the semiconductor device manufacturing method, following FIG. 7L;

FIG. 8 is a diagram illustrating an example of the sizes of a circuit chip and an array chip according to the first embodiment;

FIG. 9 is a cross sectional view illustrating an example of the configuration of a semiconductor device according to a comparative example;

FIG. 10 is a diagram illustrating an example of the sizes of a circuit chip and an array chip according to the comparative example;

FIG. 11 is a cross sectional view illustrating an example of the configuration of a semiconductor device according to a second embodiment;

FIG. 12 is a cross sectional view illustrating an example of the configuration of a semiconductor chip according to a third embodiment; and

FIG. 13 is a cross sectional view illustrating an example of the configuration of a semiconductor chip according to a fourth embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a first semiconductor chip and a second semiconductor chip. The first semiconductor chip has a first upper surface on which a first electrode pad is formed. The second semiconductor chip has a first lower surface on which a second electrode pad directly joined to the first electrode pad is formed and a second upper surface that is opposite the first lower surface and on which a third electrode pad is formed. The area of the first lower surface is smaller than the area of the first upper surface. The barycenter of the first lower surface and the barycenter of the first upper surface are located at different positions in the in-plane direction of the first upper surface.

### First Embodiment

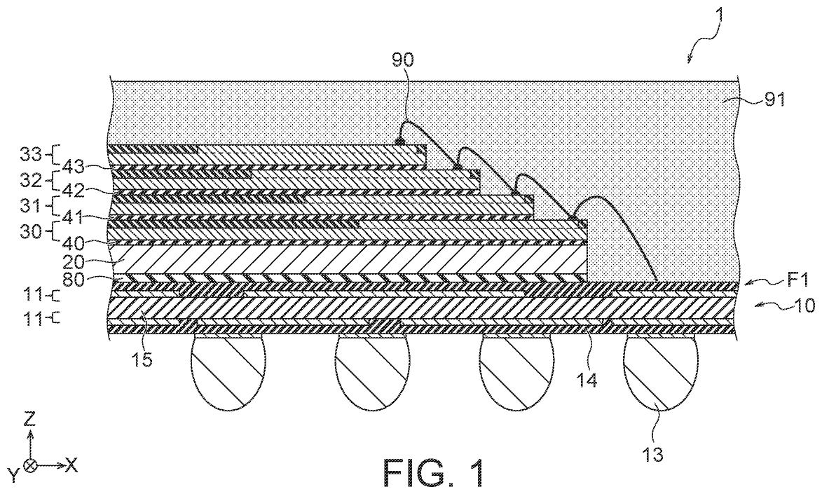

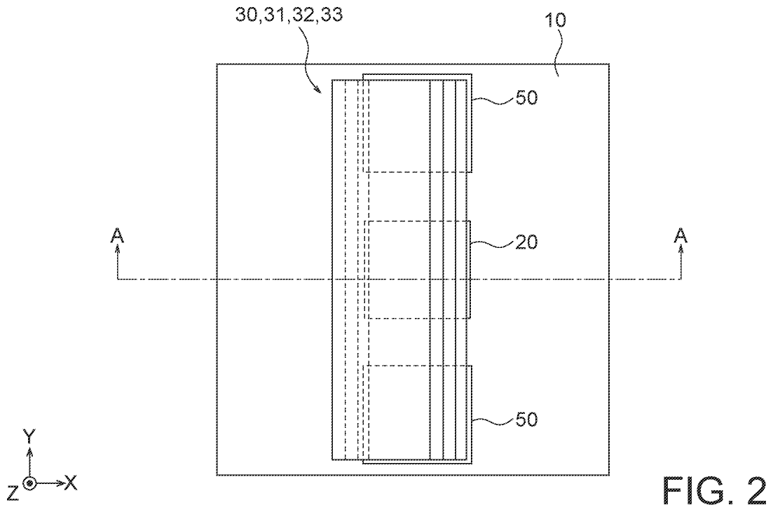

FIG. 1 is a cross sectional view illustrating an example of the configuration of a semiconductor device 1 according to a first embodiment. FIG. 2 is a plan view illustrating the example of the configuration of the semiconductor device 1 according to the first embodiment. Line A-A in FIG. 2 indicates a section corresponding to the cross sectional view of FIG. 1.

FIGS. 1 and 2 illustrate an X direction and a Y direction parallel to a front surface of a wiring substrate 10 and orthogonal to each other, and a Z direction orthogonal to the front surface of the wiring substrate 10. In the present specification, the positive Z direction is an upward direction, and the negative Z direction is a downward direction. The negative Z direction may or may not be aligned with the direction of gravity.

The semiconductor device 1 includes the wiring substrate 10, semiconductor chips 20 and 30 to 33, bonding layers 40 to 43, a spacer 50, a resin layer 80, a bonding wire 90, and a sealing resin 91. The semiconductor device 1 is, for example, a packaged NAND type flash memory. The bonding layers 40 to 43 may be resin such as a die attach film (DAF).

The wiring substrate 10 may be a printed circuit board or interposer including wiring layers 11 and an insulating layer 15. A low resistance metal such as copper (Cu), nickel (Ni), or alloy thereof is used as the wiring layers 11. An insulating material such as glass epoxy resin is used as the insulating layer 15. In the diagrams, the wiring layers 11 are provided only on front and back surfaces of the insulating layer 15. However, the wiring substrate 10 may include a multi-layer wiring structure formed by stacking a plurality of wiring layers 11 and a plurality of insulating layers 15. The wiring substrate 10 may include a penetration electrode (column-shaped electrode) penetrating through front and back surfaces thereof like an interposer.

A solder resist layer 14 provided on a wiring layer 11 is provided on the front surface (surface F1) of the wiring substrate 10. The solder resist layer 14 is an insulating layer for protecting the wiring layer 11 from a metallic material (not illustrated) connecting the semiconductor chip 20 and the wiring layers 11 and for preventing short-circuit defect.

Another solder resist layer 14 provided on a wiring layer 11 is provided on a back surface of the wiring substrate 10. Metal bumps 13 are provided on the wiring layer 11 exposed through the solder resist layer 14. The metal bumps 13 are provided to electrically connect a non-illustrated other component to the wiring substrate 10.

The semiconductor chip 20 is, for example, a controller chip configured to control a memory chip. A non-illustrated semiconductor element is provided on a surface of the semiconductor chip 20 facing the wiring substrate 10. The semiconductor element may be, for example, a complementary metal oxide semiconductor (CMOS) circuit constituting a controller. An electrode pillar (not illustrated) electrically connected to the semiconductor element is provided on a back surface (lower surface) of the semiconductor chip 20. A low resistance metallic material such as copper, nickel, or alloy thereof is used as the electrode pillar.

A metallic material is provided around the electrode pillar as a connection bump. The electrode pillar is electrically connected through the metallic material to the wiring layer 11 exposed at an opening part of the solder resist layer 14. A low resistance metallic material such as solder, silver, or copper is used as the metallic material. Accordingly, the metallic material electrically connects the electrode pillar of the semiconductor chip 20 and the wiring layer 11 of the wiring substrate 10.

The resin layer 80 is provided in a region around the metallic material and a region between the semiconductor chip 20 and the wiring substrate 10. The resin layer 80 is, for example, cured underfill resin and covers and protects the circumference of the semiconductor chip 20.

The semiconductor chip 30 is, for example, a memory chip including an NAND type flash memory. The semiconductor chip 30 is provided with a semiconductor element (not illustrated) on its front surface (upper surface). The semiconductor element may be, for example, a memory cell array and its peripheral circuit (CMOS circuit). The memory cell array may be a stereoscopic memory cell array in which a plurality of memory cells are three-dimensionally disposed. The semiconductor chip 31 is bonded on the semiconductor chip 30 with the bonding layer 41 interposed therebetween. The semiconductor chip 32 is bonded on the semiconductor chip 31 with the bonding layer 42 interposed therebetween. The semiconductor chip 33 is bonded on the semiconductor chip 32 with the bonding layer 43 interposed therebetween. Similarly to the semiconductor chip 30, the semiconductor chips 31 to 33 are, for example, memory chips including an NAND type flash memory. The semiconductor chips 30 to 33 may be the same memory chip. In the diagrams, the semiconductor chip 20 as a controller chip as well as the semiconductor chips 30 to 33 as four memory chips are stacked. However, the number of stacked semiconductor chips may be three or less or may be five or more.

As illustrated in FIG. 2, the spacer 50 is provided, for example, on a side of the semiconductor chip 20. The spacer 50 is bonded to the front surface (upper surface) of the wiring substrate 10 with a bonding layer interposed therebetween. The semiconductor chips 30 to 33 are provided above the spacer 50 and the semiconductor chip 20. The material of the spacer 50 is, for example, silicon (Si) or polyimide.

The bonding wire 90 is connected to an electrode pad provided on the wiring substrate 10 and optional electrode pads of the semiconductor chips 30 to 33. For the connection through the bonding wire 90, the semiconductor chips 30 to 33 are stacked while being displaced as corresponding to the electrode pads. The semiconductor chip 20 is flip-chip connected through the electrode pillar and thus not wire-bonded. However, the semiconductor chip 20 may be wire-bonded in addition to the connection through the electrode pillar.

The sealing resin 91 seals the semiconductor chips 20 and 30 to 33, the bonding layers 40 to 43, the spacer 50, the bonding wire 90, and the like. Accordingly, in the semiconductor device 1, the plurality of semiconductor chips 20 and 30 to 33 are constituted as one semiconductor package on the wiring substrate 10.

Details of the semiconductor chips 30 to 33 will be described below.

FIG. 3 is a cross sectional view illustrating the example of the configuration of the semiconductor device 1 according to the first embodiment. FIG. 3 illustrates the two semiconductor chips 30 and 31. Although the semiconductor chip 31 will be described below, the semiconductor chips 30, 32, and 33 have the same configuration as the semiconductor chip 31. Since the semiconductor chips 30 and 31 will be described in detail in the example illustrated in FIG. 3, illustration of the semiconductor chip 20 in FIG. 1 is omitted.

The semiconductor chip 31 includes a circuit chip CH1, an array chip CH2, and a spacer 101. The circuit chip CH1 is an example of the first chip. The array chip CH2 is an example of the second chip. The circuit chip CH1 and the array chip CH2 are semiconductor chips including semiconductor circuits.

The circuit chip CH1 functions as a control circuit (logic circuit) configured to control operation of the array chip CH2.

The circuit chip CH1 includes a semiconductor substrate 111, an interlayer insulating film 112, transistors (semiconductor element) 113, and metal electrode pads BP1.

The semiconductor substrate 111 is provided on a lower surface side of the circuit chip CH1. The semiconductor substrate 111 is, for example, a silicon (Si) substrate.

The interlayer insulating film 112 is provided on the semiconductor substrate 111. The interlayer insulating film 112 is, for example, a silicon oxide film or a multilayer film including a silicon oxide film and any other insulating film.

The plurality of transistors 113 are provided above the semiconductor substrate 111. The transistors 113 constitute a CMOS circuit as a control circuit of a memory cell array 123 of the array chip CH2. The control circuit is electrically connected to the metal electrode pads BP1.

The metal electrode pads BP1 are provided at a joining surface (bonding surface) S to the array chip CH2. The metal electrode pads BP1 are directly joined to metal electrode pads BP2 of the array chip CH2. The plurality of metal electrode pads BP1 are, for example, Cu layers.

The array chip CH2 is directly joined (bonded) to the circuit chip CH1 on the circuit chip CH1 such that the array chip CH2 is electrically connected to the circuit chip CH1. The area of a lower surface of the array chip CH2 is smaller than the area of an upper surface of the circuit chip CH1. The areas of the circuit chip CH1 and the array chip CH2 are areas when viewed in the Z direction. As clearly understood from FIG. 3, the barycenter position of the upper surface of the circuit chip CH1 in a plan view of the upper surface and the barycenter position of the lower surface of the array chip CH2 in a plan view of the lower surface are located at different positions in the in-plane direction of the upper surface of the circuit chip CH1.

For example, an insulating layer including a silicon oxide and the metal electrode pads BP2 are provided on the lower surface of the array chip CH2. The insulating layer and the metal electrode pads BP2 are flush with one another. This flush configuration includes a configuration with a step of 1 μm or smaller due to, for example, manufacturing error.

For example, an insulating layer including a silicon oxide and the metal electrode pads BP1 are provided on the upper surface of the circuit chip CH1. The insulating layer and the metal electrode pads BP1 are flush with one another. This flush configuration includes a configuration with a step of 1 μm or smaller due to, for example, manufacturing error.

The insulating layer on the lower surface of the array chip CH2 and the insulating layer on the upper surface of the circuit chip CH1 may be directly joined to each other.

The array chip CH2 includes a semiconductor substrate 121, an interlayer insulating film 122, a memory cell array (semiconductor element) 123, a contact plug C1, the metal electrode pads BP2, and a metal electrode pad WP.

The semiconductor substrate 121 is provided on an upper surface side of the array chip CH2. The semiconductor substrate 121 is, for example, a silicon (Si) substrate.

The interlayer insulating film 122 is provided below the semiconductor substrate 121. The interlayer insulating film 122 is, for example, a silicon oxide film or a multilayer film including a silicon oxide film and any other insulating film.

The memory cell array 123 is provided below the semiconductor substrate 121. The memory cell array 123 is, for example, a non-volatile memory. The memory cell array 123 includes a staircase structure part. The memory cell array 123 is electrically connected to the metal electrode pads BP2.

The contact plug C1 electrically connects a conductive layer (word line WL) of the memory cell array 123 and a metal electrode pad BP2.

The metal electrode pads BP2 are provided at the joining surface S to the circuit chip CH1. The metal electrode pads BP2 are joined to the metal electrode pads BP1 of the circuit chip CH1. The plurality of metal electrode pads BP2 are, for example, Cu layers. The metal electrode pads BP2 are examples of a second electrode pad.

The metal electrode pad WP is provided on the upper surface of the array chip CH2. The metal electrode pad WP functions as an external connection electrode pad (bonding electrode pad) of the semiconductor chips 30 to 33. Specifically, the metal electrode pad WP is connected to the bonding wire 90. Accordingly, the bonding wire 90 electrically connects the metal electrode pad WP and the wiring substrate 10. The metal electrode pad WP includes conductive metal such as nickel (Ni). The metal electrode pad WP is an example of the first electrode pad.

The spacer 101 (first member) is provided in a second region R2 different from a first region R1 in which the array chip CH2 is provided on the upper surface of the circuit chip CH1. An upper surface of the spacer 101 is substantially parallel to the upper surface of the array chip CH2.

The upper surface of the spacer 101 is flush with the upper surface of the array chip CH2. This flush configuration includes a configuration with a step of 1 μm or smaller due to manufacturing error including differences in CMP polishing speed and etching speed to be described later. The flush configuration also includes a configuration in which grooves, holes, and the like are formed at the spacer 101 and part of the upper surface of the second chip.

Specifically, a stepped part formed due to the area difference between the circuit chip CH1 and the array chip CH2 can be substantially flattened by the spacer 101. The spacer 101 of the semiconductor chip 30 supports the semiconductor chip 31 as illustrated in FIG. 3. Accordingly, the risk of chip tilt or the like at assembly can be reduced. Thus, the area of the upper surface of the array chip CH2 can be increased and stacking (die bonding) of the semiconductor chips 30 to 33 can be more appropriately performed.

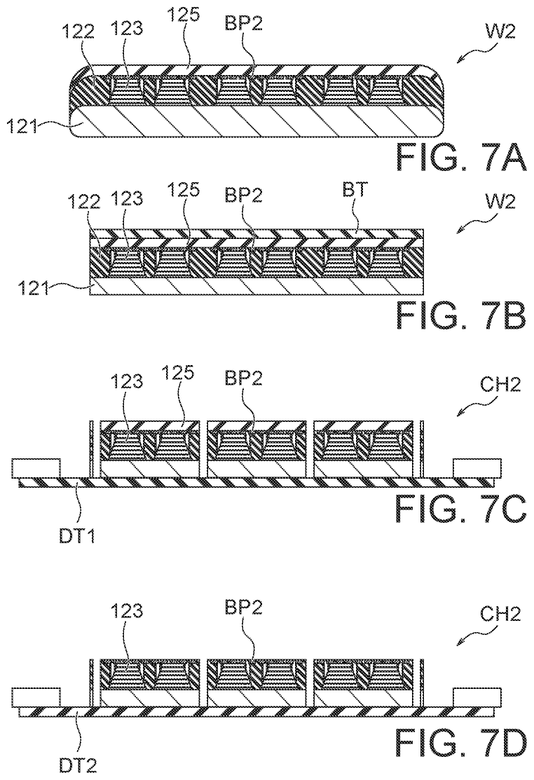

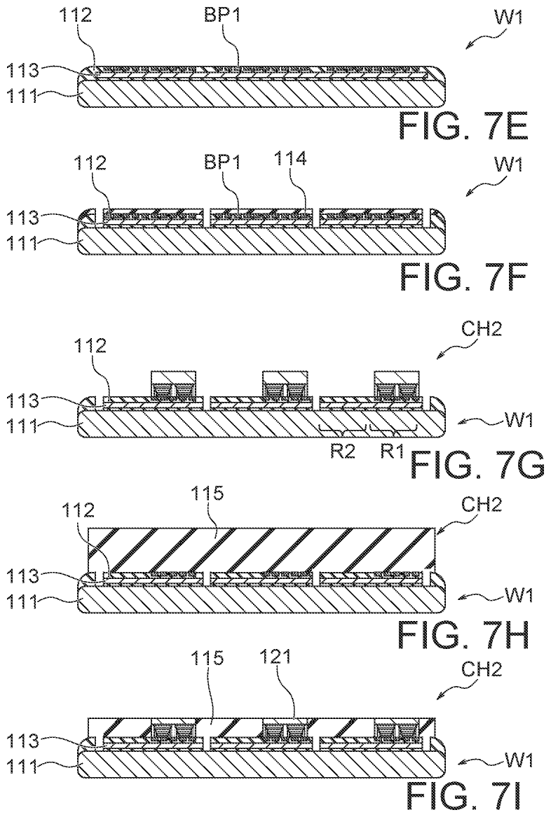

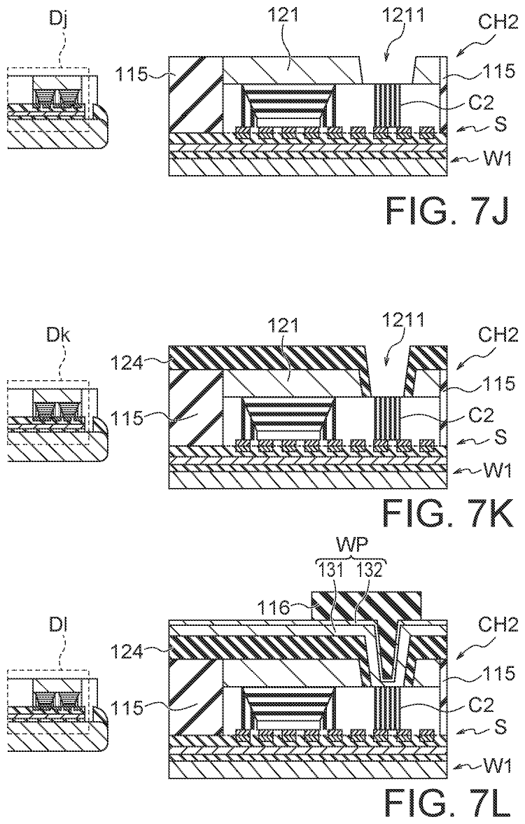

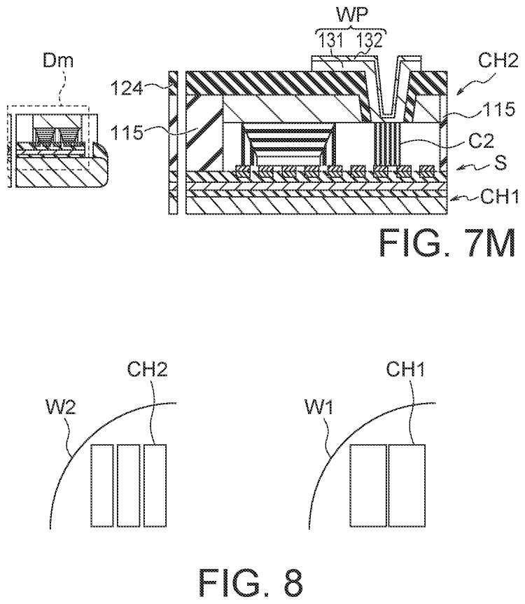

The spacer 101 includes resin such as epoxy resin. In a case where the spacer 101 is resin, the spacer 101 includes a filler. The resin of the spacer 101 may be a material different from the sealing resin 91. In this case, the size of the filler is different between the spacer 101 and the sealing resin 91. The resin of the spacer 101 may be the same material as the sealing resin 91. In this case, the size of the filler is the same between the spacer 101 and the sealing resin 91. However, the filler of the spacer 101 cut in singulation (refer to FIG. 7M) is exposed at a boundary surface between the spacer 101 and the sealing resin 91 in some cases. A side surface of the spacer 101 may directly contact a side surface of the array chip CH2. A bottom surface of the spacer 101 may directly contact the upper surface of the circuit chip CH1.

The bonding layer 41 is interposed between the semiconductor chip 30 and the semiconductor chip 31. The bonding layer 41 directly contacts the upper surfaces of the spacer 101 and the array chip CH2 included in the semiconductor chip 30 and directly contacts the lower surface of the circuit chip CH1 of the semiconductor chip 31.

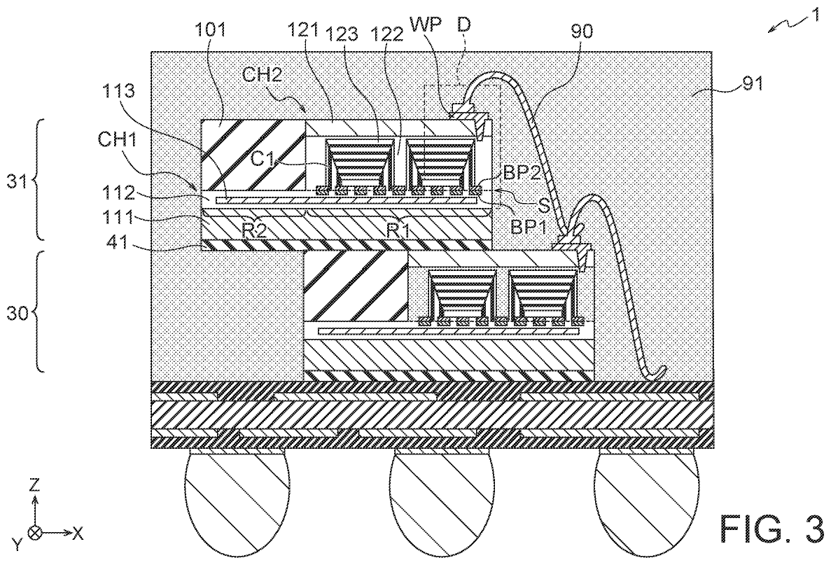

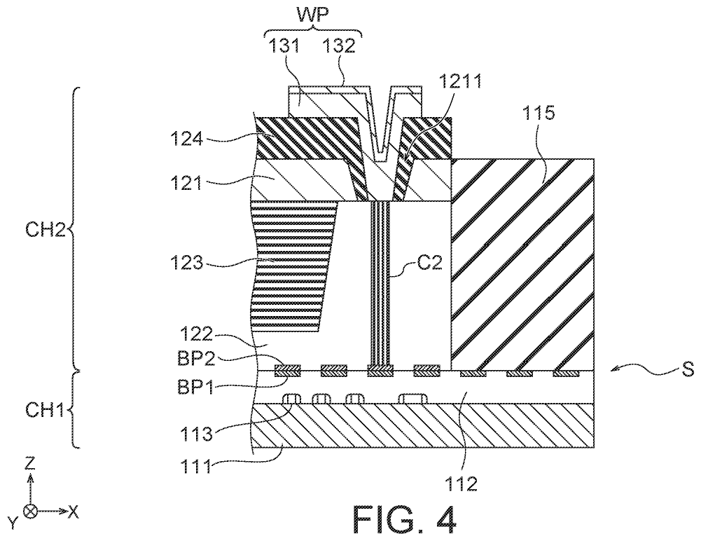

FIG. 4 is a cross sectional view illustrating the example of the configuration of the semiconductor device 1 according to the first embodiment. FIG. 4 is an enlarged view of a dashed line frame D illustrated in FIG. 3.

As illustrated in FIG. 4, a member 115 may be provided on a right side of the array chip CH2. Illustration of the member 115 is omitted in FIG. 3. The material of the member 115 is the same as the material of the spacer 101 provided on a left side of the array chip CH2 (refer to FIGS. 7H to 7M). The member 115 includes, for example, epoxy resin.

The semiconductor substrate 121 includes a recessed part 1211. The recessed part 1211 penetrates from an upper surface of the semiconductor substrate 121 to a lower surface thereof.

The array chip CH2 further includes an insulating film 124.

The insulating film 124 is a protective film (passivation film) and includes, for example, polyimide. The insulating film 124 is provided on a side surface of the recessed part 1211 and the upper surface of the semiconductor substrate 121. In the example illustrated in FIG. 4, the insulating film 124 is not provided on the member 115. This is because part of the insulating film 124 is removed so that the insulating film 124 does not remain in a dicing region for singulation of the semiconductor chips 30 to 33 (refer to FIG. 7M). However, the insulating film 124 may be provided on the member 115 or may be provided covering part of the member 115.

The metal electrode pad WP is provided above the semiconductor substrate 121. More specifically, the metal electrode pad WP is provided on the insulating film 124. The metal electrode pad WP is provided extending in the lateral direction of the recessed part 1211 from a bottom surface of the recessed part 1211. In other words, the metal electrode pad WP is formed integrally with wiring extending from the bottom surface of the recessed part 1211 to above the semiconductor substrate 121. Accordingly, the metal electrode pad WP extends penetrating through the semiconductor substrate 121.

The metal electrode pad WP further includes metal members 131 and 132.

The metal member 131 includes, for example, nickel (Ni).

The metal member 132 is provided covering the metal member 131. The metal member 132 includes, for example, gold (Au).

The array chip CH2 further includes a contact plug C2.

The contact plug (column-shaped electrode) C2 is provided penetrating through the interlayer insulating film 122 and extending from the bottom surface of the recessed part 1211 (lower surface of the metal electrode pad WP) to the metal electrode pads BP2. Accordingly, the contact plug C2 electrically connects the metal electrode pad WP and the circuit chip CH1. In other words, the metal electrode pad WP and the circuit chip CH1 are electrically connected to each other. The contact plug C2 includes conductive metal such as tungsten (W).

The configuration of the memory cell array 123 and the transistors 113 will be described below.

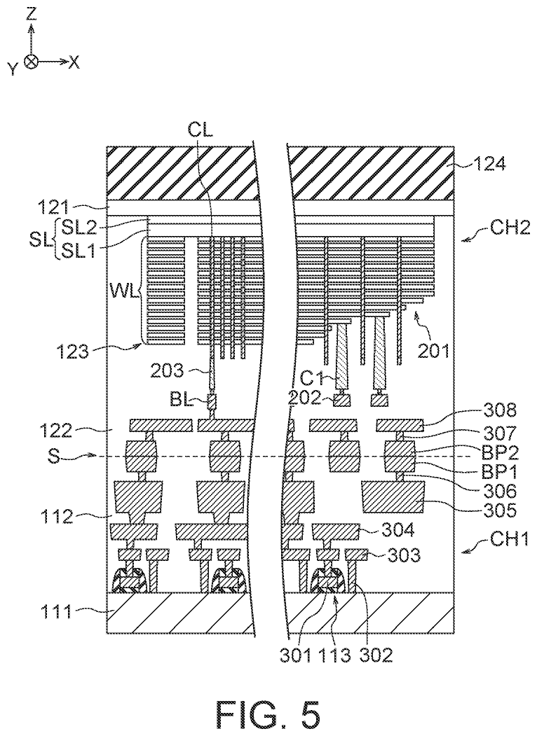

FIG. 5 is a cross sectional view illustrating an example of the configuration of the memory cell array 123 and the transistors 113 according to the first embodiment.

The array chip CH2 includes a plurality of word lines WL and a source line SL as electrode layers in the memory cell array 123. FIG. 5 illustrates a staircase structure part 201 of the memory cell array 123. Each word line WL is electrically connected to a word wiring layer 202 through the contact plug C1. A column-shaped part CL penetrating through the plurality of word lines WL is electrically connected to a bit line BL through a via plug 203 and electrically connected to the source line SL. The source line SL includes a first layer SL1 that is a semiconductor layer, and a second layer SL2 that is a metal layer.

The circuit chip CH1 includes the plurality of transistors 113. Each transistor 113 includes a gate electrode 301 provided on the semiconductor substrate 111 with a gate insulating film interposed therebetween, and a source diffusion layer and a drain diffusion layer provided in the semiconductor substrate 111, which are not illustrated. The circuit chip CH1 includes a plurality of contact plugs 302 each provided on the gate electrode 301, the source diffusion layer, or the drain diffusion layer of a transistor 113, a wiring layer 303 provided on the contact plugs 302 and including a plurality of pieces of wiring, and a wiring layer 304 provided on the wiring layer 303 and including a plurality of pieces of wiring.

The circuit chip CH1 also includes a wiring layer 305 provided on the wiring layer 304 and including a plurality of pieces of wiring, a plurality of via plugs 306 provided on the wiring layer 305, and the plurality of metal electrode pads BP1 provided on the via plugs 306. The metal electrode pads BP1 are, for example, Cu (copper) layers or Al (aluminum) layers.

The array chip CH2 includes the plurality of metal electrode pads BP2 provided on the metal electrode pads BP1, and a plurality of via plugs 307 provided on the metal electrode pads BP2. The array chip CH2 also includes a wiring layer 308 provided on the via plugs 307 and including a plurality of pieces of wiring. The metal electrode pads BP2 are, for example, Cu layers or Al layers.

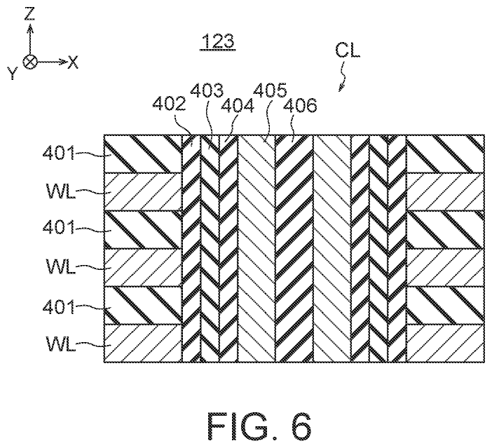

FIG. 6 is a cross sectional view illustrating an example of the configuration of the column-shaped part CL according to the first embodiment.

As illustrated in FIG. 6, the memory cell array 123 includes the plurality of word lines WL and a plurality of insulating layers 401 alternately stacked on the interlayer insulating film 122 (FIG. 5). Each word line WL is, for example, a W (tungsten) layer. Each insulating layer 401 is, for example, a silicon oxide film.

The column-shaped part CL sequentially includes a block insulating film 402, an electric charge accumulation layer 403, a tunnel insulating film 404, a channel semiconductor layer 405, and a core insulating film 406. The electric charge accumulation layer 403 is, for example, a silicon nitride film and formed on side surfaces of the word lines WL and the insulating layers 401 with the block insulating film 402 interposed therebetween. The electric charge accumulation layer 403 may be a semiconductor layer such as a polysilicon layer. The channel semiconductor layer 405 is, for example, a polysilicon layer and formed on a side surface of the electric charge accumulation layer 403 with the tunnel insulating film 404 interposed therebetween. The block insulating film 402, the tunnel insulating film 404, and the core insulating film 406 are each, for example, a silicon oxide film or a metal insulating film.

A method of manufacturing the semiconductor device 1 will be described below.

FIGS. 7A to 7M are cross sectional views illustrating an example of the method of manufacturing the semiconductor device 1 according to the first embodiment.

First, as illustrated in FIG. 7A, an array wafer W2 is prepared. For example, the memory cell array 123 is formed on the semiconductor substrate 121, and a protective film 125 is applied on the interlayer insulating film 122. The protective film 125 is, for example, an alkali-soluble film.

Subsequently, as illustrated in FIG. 7B, the array wafer W2 is provided with edge trimming, a protection tape BT is bonded, and back grinding is performed. Accordingly, the semiconductor substrate 121 is thinned. The protection tape BT is a protection tape for back grinding.

Subsequently, as illustrated in FIG. 7C, a dicing tape DT1 is bonded, the protection tape BT is peeled, a peeling surface of the protective film 125 is cleaned, and dicing is performed. Accordingly, the array wafer W2 is singulated into a plurality of array chips CH2.

Subsequently, as illustrated in FIG. 7D, the array chips CH2 are transferred onto a dicing tape DT2, the protective film 125 is newly bonded, and pre-joining treatment is performed. The pre-joining treatment is preprocessing for joining the array chips CH2 to a circuit wafer W1. The pre-joining treatment includes, for example, N₂ plasma treatment and water washing treatment.

Subsequently, as illustrated in FIG. 7E, the circuit wafer W1 is prepared. For example, the transistors 113 are formed on the semiconductor substrate 111.

Subsequently, as illustrated in FIG. 7F, a protective film 114 is applied, and singulation is performed by laser grooving. The laser grooving is performed in accordance with the size of the circuit chip CH1. Accordingly, a groove is formed around the circuit chip CH1. The groove does not necessarily need to penetrate from an upper surface of the circuit wafer W1 to a lower surface thereof. The groove formation may be performed by another method such as blade dicing, stealth dicing by laser, or etching.

Subsequently, as illustrated in FIG. 7G, the protective film 114 is removed, pre-joining treatment is performed, a plurality of array chips CH2 are joined on the circuit wafer W1, and annealing is performed. The metal electrode pads BP1 and the metal electrode pads BP2 illustrated in FIGS. 3 and 4 are joined to each other. In addition, the insulating layer on the upper surface of the circuit wafer W1 and the insulating layer on the lower surface of the array chip CH2 are joined to each other. Accordingly, the array chip CH2 is joined to the circuit wafer W1 such that the circuit wafer W1 (circuit chip CH1) and the array chip CH2 are electrically connected to each other. The annealing may be performed in forming gas (for example, reductive gas as mixture of hydrogen and nitrogen).

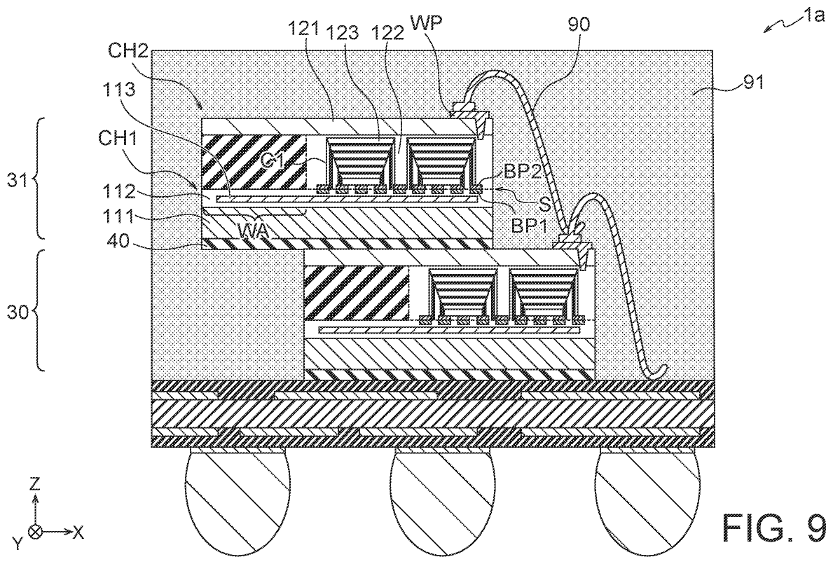

FIG. 8 is a diagram illustrating an example of the sizes of the circuit chip CH1 and the array chip CH2 according to the first embodiment. The size of each chip relative to a wafer is not limited to that in the example illustrated in FIG. 8.

As illustrated in FIG. 8, the area of the lower surface of the array chip CH2 is smaller than the area of the upper surface of the circuit chip CH1. Accordingly, as illustrated in FIG. 7G, the first region R1 in which the array chip CH2 is provided and the second region R2 in which the array chip CH2 is not provided exist on the circuit chip CH1 (circuit wafer W1). Moreover, the barycenter position of the lower surface of the array chip CH2 is different from the barycenter position of the upper surface of the circuit chip CH1 in the in-plane direction.

Subsequently, as illustrated in FIG. 7H, the member 115 is formed on the circuit wafer W1 and the array chip CH2, and bevel polishing of the member 115 is performed. The member 115 is resin such as epoxy resin. FIG. 7H illustrates that the upper and side surfaces of the array chip CH2 are covered by the member 115.

Subsequently, as illustrated in FIG. 7I, back grinding is performed, part of the member 115 and part of the semiconductor substrate 121 of the array chip CH2 are removed. Thereafter, degas annealing is performed. Accordingly, the height of an upper surface of the member 115 becomes substantially same as the height of the upper surface of the semiconductor substrate 121 of the array chip CH2. In other words, the upper surface of the member 115 becomes flush with the semiconductor substrate 121 of the array chip CH2. This flush configuration includes a configuration with a step of 1 μm or smaller due to manufacturing error including differences in CMP polishing speed and etching speed to be described later.

The back grinding is performed by, for example, chemical mechanical polishing (CMP). Other methods of removing part of the member 115 and part of the semiconductor substrate 121 of the array chip CH2 for the flush configuration include etching with drug solution or gas, and grinding with a whetstone. These methods may be combined.

FIGS. 7J to 7M described below each illustrate one array chip CH2. The right side in each of FIGS. 7J to 7M is an enlarged view of the corresponding one of dashed line frames Dj to Dm illustrated on the left side in FIGS. 7J to 7M.

Subsequently, as illustrated in FIG. 7J, the recessed part 1211 is formed through the semiconductor substrate 121. Specifically, the recessed part 1211 penetrating from the upper surface of the semiconductor substrate 121 to the lower surface thereof is formed at the semiconductor substrate 121 provided on the upper surface side of the array chip CH2. Accordingly, an upper end of the contact plug C2 is exposed. The recessed part 1211 is formed by, for example, lithography and reactive ion etching (RIE).

Subsequently, as illustrated in FIG. 7K, the insulating film 124 is formed. The insulating film 124 is formed on, for example, the side surface of the recessed part 1211 and the semiconductor substrate 121. The insulating film 124 is formed by, for example, lithography and curing. The insulating film 124 has an opening at the recessed part 1211. Subsequently, as illustrated in FIG. 7L, a barrier metal (not illustrated) is formed and the metal members 131 and 132 are formed.

Accordingly, the metal electrode pad WP is formed at the upper surface of the array chip CH2. More specifically, the metal electrode pad WP that is integrated with wiring extending from the bottom surface of the recessed part 1211 to above the semiconductor substrate 121 and is provided above the semiconductor substrate 121 is formed. The barrier metal is provided below the metal members 131 and 132 and includes, for example, titanium (Ti). The barrier metal and the metal members 131 and 132 are formed by, for example, lithography and sputtering. More specifically, the barrier metal and the metal members 131 and 132 are formed on the entire surface by sputtering or the like, and thereafter a resist 116 is patterned by photolithography and used as a mask for etching.

Subsequently, as illustrated in FIG. 7M, the resist 116 is peeled, an under-bump-metal (UBM) plate (not illustrated) is formed, and dicing is performed. In this case, cutting may be performed with a blade having a width smaller than the width of the groove formed in FIG. 7A. Accordingly, the circuit wafer W1 is singulated into a plurality of circuit chips CH1 (semiconductor chips 30 to 33). The UBM plate is formed by, for example, wet plating. In addition, the spacer 101 illustrated in FIG. 3 is formed through dicing of the member 115.

Thereafter, the semiconductor chips 30 to 33 formed through the process illustrated in FIG. 7M are mounted on the wiring substrate 10 and a package assembling process is performed. Accordingly, the semiconductor device 1 illustrated in FIGS. 1 to 3 is completed.

Before the circuit wafer W1 is singulated into the circuit chips CH1 (semiconductor chips 30 to 33), wiring may be connected to each metal electrode pad WP to measure electric properties of the semiconductor chips 30 to 33. Accordingly, chip selection can be performed. Thus, each metal electrode pad WP also functions as a probe terminal for the wafer before being singulated into the semiconductor chips 30 to 33.

As described above, according to the first embodiment, the area of the array chip CH2 is smaller than the area of the circuit chip CH1. The array chip CH2 includes the metal electrode pad WP provided at the upper surface of the array chip CH2. Accordingly, as illustrated in FIG. 8, it is possible to reduce waste on the array wafer W2 along with miniaturization of the memory cell array 123. Thus, it is possible to form a larger number of array chips CH2 on the array wafer W2.

### Comparative Example

FIG. 9 is a cross sectional view illustrating an example of the configuration of a semiconductor device 1a according to a comparative example. The comparative example is different from the first embodiment in that the area of the array chip CH2 is substantially equal to the area of the circuit chip CH1.

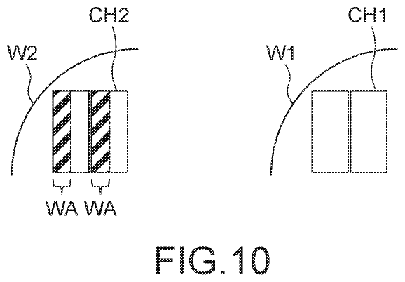

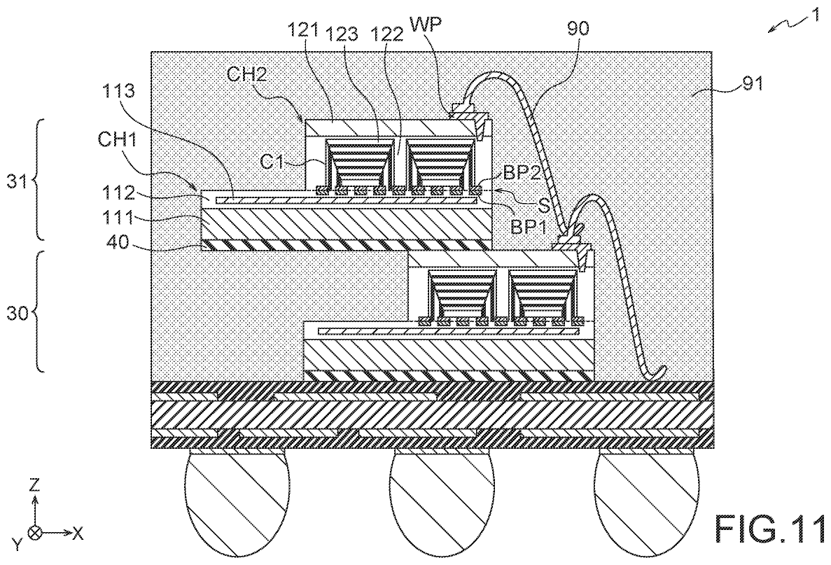

FIG. 10 is a diagram illustrating an example of the sizes of the circuit chip CH1 and the array chip CH2 according to the comparative example.

As illustrated in FIG. 10, the area of the array chip CH2 is substantially equal to the area of the circuit chip CH1. In the comparative example, the semiconductor chips 30 to 33 are formed by bonding the circuit wafer W1 and the array wafer W2 to each other and singulating the bonded wafers. However, a mismatch between the element area of the array chip CH2 and the element area of the circuit chip CH1 increases along with miniaturization of the memory cell array 123. In this case, as illustrated in FIGS. 9 and 10, the area of a region WA increases as the element area of the memory cell array 123 decreases. The region WA is an unnecessary region in which the memory cell array 123 is not provided on the array chip CH2.

However, in the first embodiment, a plurality of array chips CH2 are joined to the circuit wafer W1 as illustrated in FIG. 7G. As illustrated in FIG. 8, the memory cell array 123 is formed without providing the unnecessary region WA on the array wafer W2. Accordingly, the unnecessary region WA can be eliminated, and a larger number of array chips CH2 can be formed on the array wafer W2.

As illustrated in FIG. 3, the spacer 101 is provided to fill an empty region (step) formed due to the area difference between the circuit chip CH1 and the array chip CH2. Accordingly, the risk of chip tilt or the like at assembly can be reduced. Thus, the area of the upper surface of the array chip CH2 can be increased and stacking (die bonding) of the semiconductor chips 30 to 33 can be more appropriately performed.

### Second Embodiment

FIG. 11 is a cross sectional view illustrating an example of the configuration of the semiconductor device 1 according to a second embodiment. The second embodiment is different from the first embodiment in that no spacer 101 is provided.

No spacer 101 may be provided as in the second embodiment. In the semiconductor device 1 according to the second embodiment, a larger number of array chips CH2 can be formed on the array wafer W2 as in the first embodiment.

### Third Embodiment

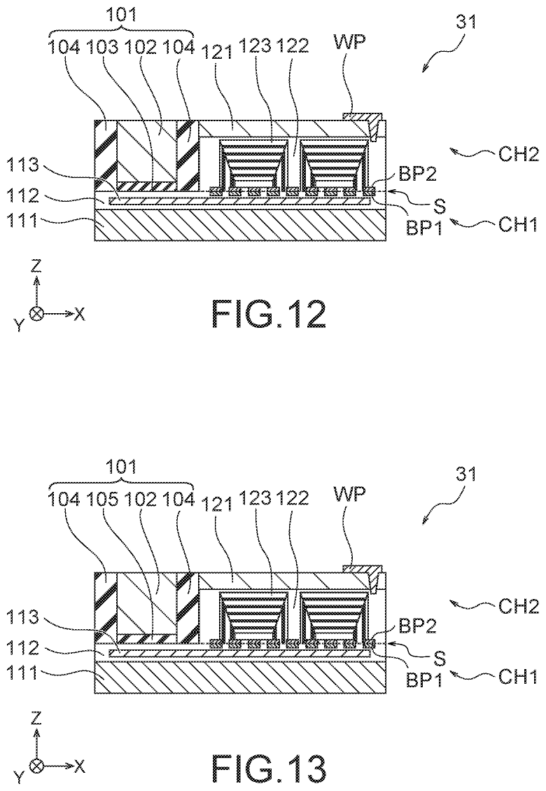

FIG. 12 is a cross sectional view illustrating an example of the configuration of the semiconductor chips 30 to 33 according to a third embodiment. In FIG. 12, the semiconductor chip 31 is illustrated as an example. The third embodiment is different from the first embodiment in the configuration of the spacer 101.

The spacer 101 includes a spacer chip 102 (first member), a bonding layer 103, and a member 104.

An upper surface of the spacer chip (dummy chip) 102 is substantially parallel to the upper surface of the array chip CH2.

The bonding layer 103 is provided between the circuit chip CH1 and the spacer chip 102. The bonding layer 103 is, for example, a die attach film (DAF).

The member 104 is provided around the spacer chip 102. The member 104 includes resin such as epoxy resin.

The spacer chip 102 includes, for example, silicon (Si). However, the spacer chip is not limited thereto, and for example, may be resin. The spacer chip 102 preferably includes, for example, a material harder than the member 104. Accordingly, the semiconductor chips 30 to 33 stacked on the spacer 101 can be more appropriately supported. Moreover, the spacer chip 102 preferably includes a material having a thermal expansion coefficient lower than that of the member 104. Accordingly, the height of the spacer 101 can be easily adjusted. As a result, the semiconductor chips 30 to 33 stacked on the spacer 101 can be more appropriately supported.

The configuration of the spacer 101 may be changed as in the third embodiment. With the semiconductor device 1 according to the third embodiment, it is possible to obtain the same effects as in the first embodiment.

### Fourth Embodiment

FIG. 13 is a cross sectional view illustrating an example of the configuration of the semiconductor chips 30 to 33 according to a fourth embodiment. In FIG. 13, the semiconductor chip 31 is illustrated as an example. The fourth embodiment is different from the third embodiment in that an insulating film 105 is provided in place of the bonding layer 103.

The spacer 101 includes the insulating film 105. The insulating film 105 is provided in contact with the interlayer insulating film 112 provided on the upper surface of the circuit chip CH1 between the circuit chip CH1 and the spacer chip 102. The insulating film 105 and the interlayer insulating film 112 are, for example, tetra-ethoxy silane (TEOS). The insulating film 105 and the interlayer insulating film 112 are directly joined to each other by using OH radicals on a surface (interface). Accordingly, the spacer chip 102 is bonded to the circuit chip CH1.

The insulating film 105 may be provided in place of the bonding layer 103 as in the fourth embodiment. With the semiconductor device 1 according to the fourth embodiment, it is possible to obtain the same effects as in the third embodiment.

### Other Embodiments

(a) In the above-described embodiments, the array chip CH2 of each of the semiconductor chips 30 to 33 includes a stereoscopic memory cell array in which a plurality of memory cells are three-dimensionally disposed. Instead, the array chip CH2 may be, for example, a two-dimensional memory cell array or an image sensor. Alternatively, the array chip CH2 may be any other memory element such as a DRAM or an SRAM instead of an NAND type flash memory. The array chip CH2 may be, for example, a CMOS circuit element.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first semiconductor chip having a first upper surface on which a first electrode pad is formed; and
a second semiconductor chip having a first lower surface on which a second electrode pad directly joined to the first electrode pad is formed and a second upper surface that is opposite the first lower surface and on which a third electrode pad is formed, wherein
the area of the first lower surface is smaller than the area of the first upper surface, and
the barycenter of the first lower surface and the barycenter of the first upper surface are located at different positions in the in-plane direction of the first upper surface.

2. The semiconductor device according to claim 1, wherein
the second semiconductor chip further includes a semiconductor substrate on the second upper surface side of the second semiconductor chip,
a recessed part penetrating through the semiconductor substrate is formed at the semiconductor substrate,
the third electrode pad is formed integrally with wiring extending from a bottom surface of the recessed part to above the semiconductor substrate, and
the third electrode pad and the first semiconductor chip are electrically connected to each other.

3. The semiconductor device according to claim 2, wherein the second semiconductor chip further includes a column-shaped electrode provided extending from the bottom surface of the recessed part to the second electrode pad.

4. The semiconductor device according to claim 1, further comprising:
a wiring substrate on which a fourth electrode pad is provided; and
a wire electrically connecting the third electrode pad and the fourth electrode pad.

5. The semiconductor device according to claim 1, wherein
the first upper surface includes a first region and a second region different from the first region, the first region being directly joined to the first lower surface,
a first member having a third upper surface is provided in the second region, and
the third upper surface of the first member is flush with the second upper surface.

6. The semiconductor device according to claim 5, wherein a side surface of the first member directly contacts a side surface of the second semiconductor chip.

7. The semiconductor device according to claim 5, further comprising a first resin provided between the first semiconductor chip and the first member.

8. The semiconductor device according to claim 6, further comprising a second insulating film provided between the first member and a first insulating film provided on the first upper surface of the first semiconductor chip.

9. The semiconductor device according to claim 1, wherein
the second semiconductor chip includes a non-volatile memory, and
the first semiconductor chip includes a control circuit configured to control the non-volatile memory.

10. The semiconductor device according to claim 5, further comprising:
a third semiconductor chip having a third lower surface; and
a second resin directly contacting the third lower surface of the third semiconductor chip, the third upper surface of the first member, and the second upper surface of the second semiconductor chip.

11. A semiconductor device manufacturing method comprising:
forming, on a wafer, a plurality of first semiconductor chips each provided with a first electrode pad on a first upper surface;
providing a second semiconductor chip having a first lower surface on which a second electrode pad is formed on one of the plurality of first semiconductor chips such that the first electrode pad and the second electrode pad are directly joined to each other;
forming a third electrode pad on a second upper surface opposite the first lower surface of the second semiconductor chip; and
singulating the plurality of first semiconductor chips, wherein
the area of the first lower surface is smaller than the area of the first upper surface, and
the barycenter of the first lower surface and the barycenter of the first upper surface are located at different positions in the in-plane direction of the first upper surface.

12. The semiconductor device manufacturing method according to claim 11, further comprising:
forming a first member to cover the first semiconductor chip and the second semiconductor chip; and
removing part of the first member and part of the second semiconductor chip such that the second upper surface of the second semiconductor chip and a third upper surface of the first member are flush with each other.

13. The semiconductor device manufacturing method according to claim 12, further comprising cutting the wafer to singulate the plurality of first semiconductor chips into the individual first semiconductor chips.

14. The semiconductor device manufacturing method according to claim 12, further comprising:
forming a groove by removing part of the wafer before joining the second semiconductor chip and the first semiconductor chip to each other; and
singulating the plurality of first semiconductor chips into the individual first semiconductor chips after forming the first member.

15. The semiconductor device manufacturing method according to claim 12, further comprising disposing a third semiconductor chip having a third lower surface on the second semiconductor chip with a first resin interposed between the second and third semiconductor chips, wherein the first resin directly contacts the third lower surface of the third semiconductor chip, a third upper surface of the first member, and the second upper surface of the second semiconductor chip.
